(19) United States
(12) Patent Application Publication
(10) Pub. No.: US 2020/0259061 A1
(43) Pub. Date: Aug. 13, 2020

(54) High-Temperature Fiber-Free Thermocouple

(71) Applicant: TE Wire & Cable LLC, Saddle Brook, NJ (US)

(72) Inventors: Volodymyr Fedorchak, Mount Tabor, NJ (US); Mark Peters, Midland Park, NJ (US); Robert M. Canny, Saddle Brook, NJ (US)

(21) Appl. No.: 16/788,621

(22) Filed: Feb. 12, 2020

Related U.S. Application Data
(60) Provisional application No. 62/804,439, filed on Feb. 12, 2019.

(51) Int. Cl. H01L 35/32; H01L 35/08; H01L 35/34; G01K 7/02

(52) U.S. Cl. CPC H01L 35/32; H01L 35/08; G01K 7/023; G01K 7/028; H01L 35/34

(57) ABSTRACT

The present invention relates to a high-temperature thermocouple with a thermocouple wire including two dissimilar wires twisted together and covered with a polyimide-based leak-proof insulation coating. The thermocouple wire may include a welded hot junction attaching the two dissimilar wires together on one end and may be connected to a thermocouple connector located at an opposite end. A method for making the high-temperature thermocouple may include coating a pair of dissimilar wires with a leak-proof polyimide-based insulation coating by dipping of dissimilar wires in a liquid polyimide-based solution and curing the dissimilar wires with heat. The method may also include twisting the dissimilar wires around themselves, welding together the dissimilar wires to each other creating a welded hot junction, and attaching the opposite end of the dissimilar wires to a thermocouple connector. The leak-proof insulation coating and thermocouple connector may be rated for 800 degrees F. and 150 PSI.

### CROSS-REFERENCE TO RELATED APPLICATIONS

This application claims priority to U.S. Provisional Patent Application No. 62/804,439, filed Feb. 12, 2019 which is incorporated herein by reference in its entirety and made a part hereof.

### FIELD OF THE INVENTION

The field of invention for this disclosure relates to high-temperature thermocouples.

### BACKGROUND

In the composite curing process in composite autoclaves, it is desirable to run cure cycles between 300 and 800 degrees F. In the past, the only thermocouples available over 600 degrees F. have been fiberglass insulated. However, fiberglass is extremely brittle, flaky, difficult to work with, and can often cause contamination in the composite part. Additionally, fiberglass is not leak-proof at 90-150 PSI, which is the most common cure pressure of composite autoclaves. For this reason, the fiberglass thermocouples require additional handling during the layup process. An 800 degree F. rated, fiber-free thermocouple with leak-proof insulation at 90-150 PSI would address all of the problems above.

### BRIEF DESCRIPTION OF THE DRAWINGS

FIG. 1 illustrates a top perspective view of an example embodiment of a high-temperature fiber-free thermocouple according to one or more aspects described herein;

FIG. 2 illustrates another top perspective view of the example embodiment of the high-temperature fiber-free thermocouple according to one or more aspects described herein; and

FIG. 3 illustrates another top perspective view of the example embodiment of the high-temperature fiber-free thermocouple according to one or more aspects described herein.

Further, it is to be understood that the drawings may represent the scale of different components of one single embodiment; however, the disclosed embodiments are not limited to that particular scale.

### SUMMARY OF INVENTION

The following presents a general summary of aspects of the invention in order to provide a basic understanding of the invention and various features of it. This summary is not intended to limit the scope of the invention in any way, but it simply provides a general overview and context for the more detailed description that follows.

The present disclosure provides a device and a fiber-free thermocouple that achieves 800 degree F. capability with leak-proof insulation at 90-150 PSI and as high as 200 PSI, which are all critical features during the composite manufacturing process.

In one embodiment in accordance with aspects of the disclosure, a high-temperature thermocouple includes a thermocouple wire, a welded hot junction located at a first end of the thermocouple wire, and a high-temperature thermocouple connector located at a second end opposite the first end of the thermocouple wire. The thermocouple wire may include a first conductor and a second conductor twisted together. The first conductor and the second conductor may be covered with a polyimide-based leak-proof insulation coating. The first conductor and the second conductor may be dissimilar wires. The welded hot junction may attach the first conductor and the second conductor of the thermocouple wire. Further, the thermocouple wire and the high-temperature thermocouple connector may be rated at 800 degrees F. and up to 150 PSI. The twisted first conductor and the second conductor may have a lay length of between 0.3 and 2.5 inches. The polyimide-based insulation coating may be rated at 800 degrees F. and provides a leak-proof insulation up to 150 PSI. The high-temperature thermocouple connector may be coated with a high-temperature polyimide resin. The first conductor and the second conductor may be between size 20-36 AWG. The insulation coating may have a thickness of approximately 0.005 inches. The first conductor and the second conductor may be dipped in a polyimide precursor-polyamic acid and heat-cured. Additionally, the welded hot junction may be insulated in one of a fluoropolymer or a polyimide-based material. Further, the thermocouple wire and the high-temperature thermocouple connector may be rated at 200 PSI.

In another embodiment in accordance with aspects of the disclosure, a high-temperature thermocouple may be disclosed that includes a thermocouple wire that includes a pair of dissimilar wires twisted around each other, a welded hot junction located at a first end of the thermocouple wire attaching the pair of dissimilar wires, and a high-temperature thermocouple connector located at a second end opposite the first end of the thermocouple wire. The thermocouple wire may be covered with a polyimide-based leak-proof insulation coating wherein the polyimide-based insulation coating is rated at 800 degrees F. and provides a leak-proof insulation up to 150 PSI. Additionally, the welded hot junction may be insulated with one of a fluoropolymer or a polyimide-based material. Further, the thermocouple wire may be rated at 800 degrees F. and up to 150 PSI.

Additionally, in another embodiment in accordance with aspects of the disclosure, a method for making a high-temperature thermocouple may include the following steps: coating a pair of dissimilar wires with a leak-proof insulation coating, the insulation coating is a polyimide-based insulation coating, wherein the coating includes dipping the pair of dissimilar wires in a liquid polyimide-based solution and curing the pair of dissimilar wires with heat; twisting the pair of dissimilar wires around themselves with a lay length between approximately 0.3 and 2.5 inches; welding together the pair of dissimilar wires to each other at a first end, thereby creating a welded hot junction located at the first end of the pair of dissimilar wires; and attaching a second end opposite the first end of the pair of dissimilar wires to a high-temperature thermocouple connector. Additionally, the leak-proof insulation coating and high-temperature thermocouple connector may be rated for 800 degree F. and 150 PSI. Further, the liquid polyimide-based solution and insulation coating may be a polyimide precursor-polyamic acid.

The details of these and other embodiments of the present invention are set forth in the accompanying drawings and the descriptions below. Other features and advantages of the invention will be apparent from the description and the drawings.

### DETAILED DESCRIPTION OF EMBODIMENTS

In the following description of various examples of the invention, reference is made to the accompanying drawings, which form a part hereof, and in which are shown by way of illustration various example structures, systems, and steps in which aspects of the invention may be practiced. It is to be understood that other specific arrangements of parts, structures, example devices, systems, and steps may be utilized and structural and functional modifications may be made without departing from the scope of the present invention. Also, while the terms “top,” “bottom,” “front,” “back,” “side,” and the like may be used in this specification to describe various example features and elements of the invention, these terms are used herein as a matter of convenience, e.g., based on the example orientations shown in the figures. Nothing in this specification should be construed as requiring a specific three-dimensional orientation of structures in order to fall within the scope of this invention.

The following terms are used in this specification, and unless otherwise noted or clear from the context, these terms have the meanings provided below.

“Plurality,” as used herein, indicates any number greater than one, either disjunctively or conjunctively, as necessary, up to an infinite number.

“Connected,” as used herein, indicates that components may be connected directly being physically contacting each other or connected indirectly where the components are connected indirectly where the components do not physically contact, but have one or more intermediate components positioned between them.

In the following description of the various embodiments, reference is made to the accompanying drawings, which form a part hereof, and in which is shown, by way of illustration, various embodiments in which aspects of the disclosure may be practiced. It is to be understood that other embodiments may be utilized and structural and functional modifications may be made without departing from the scope and spirit of the present disclosure.

In general, aspects of this invention relate to a high-temperature fiber-free thermocouple 100 that achieves 800-degree F. capability with leak-proof insulation at 90-200 PSI. Aspects of this invention relate to a high-temperature thermocouple with a thermocouple wire including two dissimilar wires twisted together and covered with a polyimide-based leak-proof insulation coating. The thermocouple wire may include a welded hot junction attaching the two dissimilar wires together on one end and may be connected to a thermocouple connector located at an opposite end. A method for making the high-temperature thermocouple may include coating a pair of dissimilar wires with a leak-proof polyimide-based insulation coating by dipping of dissimilar wires in a liquid polyimide-based solution and curing the dissimilar wires with heat. The method may also include twisting the dissimilar wires around themselves, welding together the dissimilar wires to each other creating a welded hot junction, and attaching the opposite end of the dissimilar wires to a thermocouple connector. The leak-proof insulation coating and thermocouple connector may be rated for 800 degrees F. and 150 PSI.

Further, the high-temperature fiber-free thermocouple 100 is the next generation of temperature sensing products for manufacturing of advanced thermoplastic composites. This new high-temperature fiber-free thermocouple 100 has superior chemical resistance, abrasion resistance, and high tensile strength. Additionally, the high-temperature fiber-free thermocouple 100 retains the same proven characteristics of other product lines. The high-temperature fiber-free thermocouple 100 does not melt and can withstand up to at least 400° C. (752° F.) or approximately 800° F. processing temperatures, not leak under pressure or vacuum environment once sealed under the bagging film, and not unravel like typical polyimide films. The high-temperature fiber-free thermocouple 100 can handle thermoplastic composites, such as polyetherketoneketone (PEKK), polyetheretherketone (PEEK), and polyaryletherketone (PAEK) and these thermoplastic composite processing temperatures with better handling characteristics for operators. The unique manufacturing process of the high-temperature fiber-free thermocouple 100 removes solvents and uses a method to form a non-soluble, non-melting coating with very high heat and chemical resistance combined with best in class adhesion properties. More detailed descriptions of aspects of this invention follow.

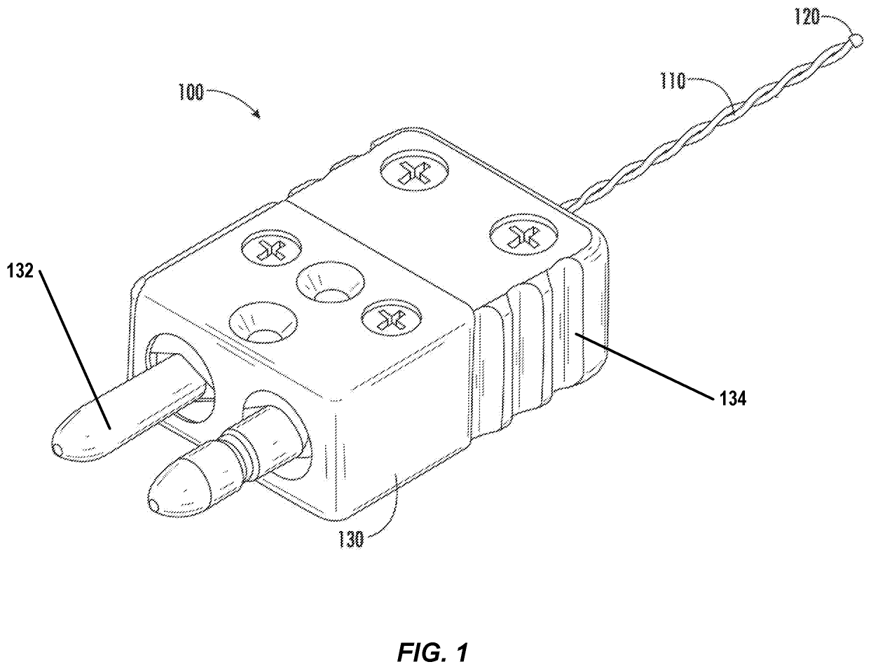

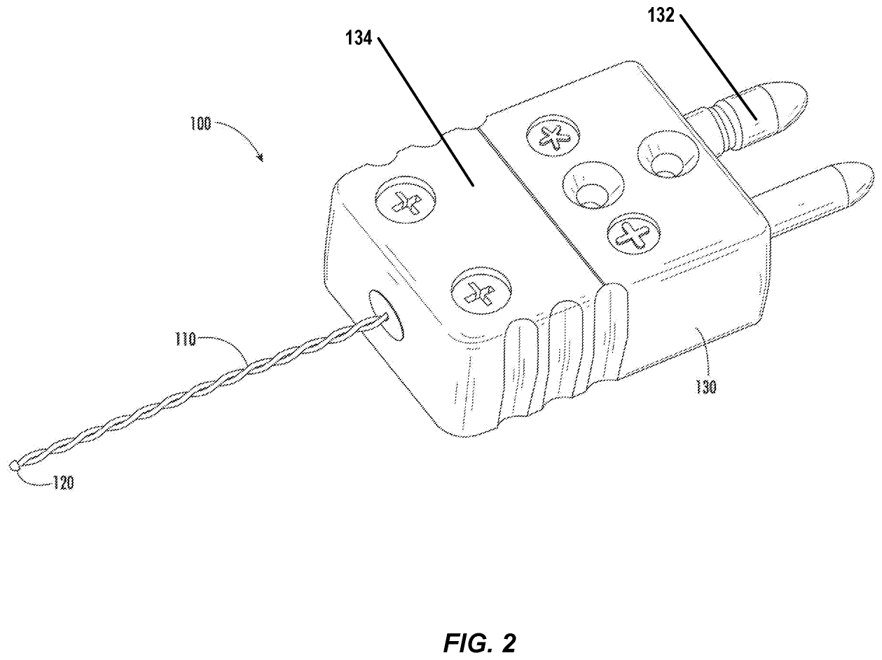

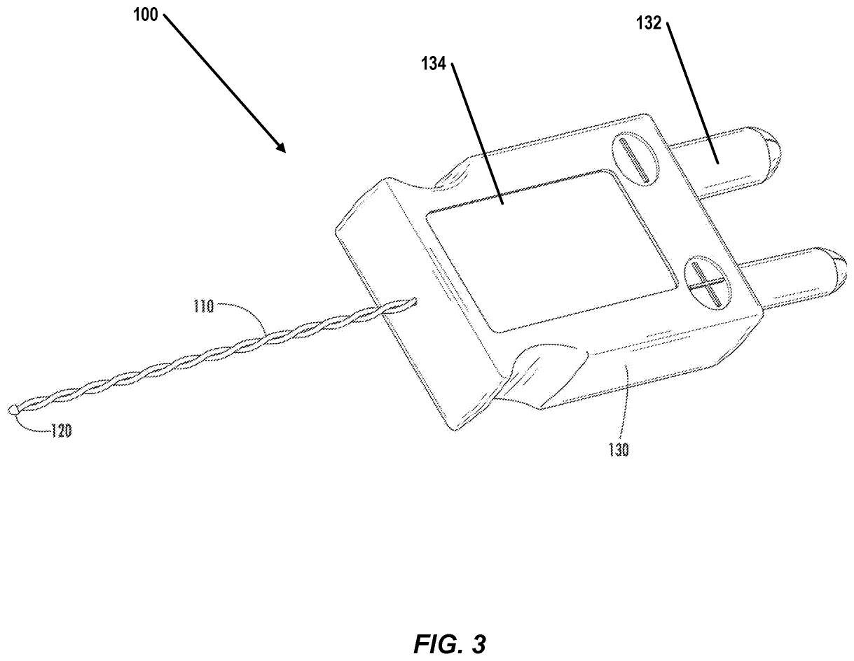

As illustrated in FIGS. 1-3, the invention consists of a high-temperature fiber-free thermocouple 100 that includes a polyimide-based insulation coated over thermocouple wire 110, a welded “hot” junction 120, and a high-temperature thermocouple connector 130. The temperature rating of the high-temperature thermocouple 100, to include both the thermocouple wire 110 and the thermocouple connector 130, may be as high as 800 degree F. The pressure rating of the high-temperature thermocouple 100, to include both the thermocouple wire 110 and the thermocouple connector 130, may be 150 PSI. Additionally, in another embodiment of the present invention, the pressure rating of the high-temperature thermocouple 100, to include both the thermocouple wire 110 and the thermocouple connector 130, may be as high as 200 PSI.

As illustrated in FIGS. 1-3, the thermocouple wire 110 may include two ends. At one end, the thermocouple 110 may be connected to the thermocouple connector 130. An opposite end of the thermocouple wire 110 may include a welded “hot” junction 120. In other embodiments without departing from the invention, a second thermocouple connector 130 may be utilized instead of the welded “hot” junction 120, thereby creating a thermocouple extension.

As illustrated in FIGS. 1-3, the high-temperature thermocouple 100 may include a thermocouple wire 110. The thermocouple wire 110 may include two dissimilar conductors twisted around one another. The two dissimilar conductors may be any metals known and used in the art of thermocouples. The thermocouple wire 110 may be coated with a high-temperature polyimide resin coating providing the insulation. Further, the insulation of the thermocouple wire 110 may include a polyimide precursor-polyamic acid that is dipped and heat cured. The insulation of the thermocouple wire 110 may be rated at 800 F and up to 200 PSI. The insulation thickness of the thermocouple wire 110 may be approximately 0.005 inches. The thermocouple wire 110 may have an AWG size of the individual conductors that is in the range of 20-36. The wire length of the thermocouple wire 110 may be any length. The lay length of the thermocouple wire 110 may be approximately 0.38 to 2.5 inches.

Additionally, as described above, the high-temperature thermocouple 100 may include a thermocouple connector 130. As illustrated in FIGS. 1-3, the thermocouple connector 130 may be any standard thermocouple connector 130 with two prongs 132 extending from a connector housing 134. The thermocouple connector 130 may include a plurality of prongs 132 or one or more prongs 132 without departing from this invention. Additionally, the thermocouple connector 130 may include different shapes for the connector housing 134 without departing from this invention. The thermocouple connector 130 may be any thermocouple type. Additionally, the thermocouple connector 130 may include any connector style without departing from this invention. The abrasion resistance of the high-temperature thermocouple 100, the thermocouple connector 130, and the connector housing 134 may be standard.

Additional aspects of the disclosure relate to a method for providing or manufacturing a high-temperature thermocouple 100 as described above, including the thermocouple wire 110 and assembling the thermocouple wire 110 and the thermocouple connector 130 described above. In other embodiments, different types of high-temperature thermocouples 100 can be manufactured according to the principles described herein.

The method of manufacturing a high-temperature thermocouple 100 may include coating two dissimilar wires of a thermocouple wire 110 with an insulation coating. In an aspect of the invention, the insulation coating may be a polyimide-based insulation coating. The thermocouple wire 110 and two dissimilar wires may be coated using a dipping process, where a liquid polyimide-based solution is applied to the thermocouple wires and two dissimilar wires 110 and cured with heat. For example, the liquid polyimide-based solution and coating may be a polyimide precursor-polyamic acid. The thermocouple wire 110 may be dipped and heat cured in the polyimide precursor-polyamic acid to provide the insulation. The two dissimilar wires 110 may then be twisted with a lay length between approximately 0.38 and 2.50 inches. The two dissimilar wires may then be attached together at one end of the thermocouple wire 110 with a welding process for the welded “hot” junction 120. On the opposite end of the thermocouple wire 110, a high-temperature thermocouple connector 130 may be attached.

At least one inventive aspect and unexpected result of the high-temperature fiber-free thermocouple 100 is that it was not expected that the dipping and curing with a polyimide precursor-polyamic acid would produce a leak-proof insulation over a thermocouple conductor. This has never been seen in the art before.

In another embodiment of the present invention, the hot junction (sensor end) 120 may be covered or dipped to insulate the welded “hot” junction 120 from a conductive surface or isolate from environmental exposure. This insulation could be a fluoropolymer or polyimide-based material.

Additionally, in another embodiment without departing from the invention, the high-temperature fiber-free thermocouple 100 does not need to have a hot junction end 120 as illustrated in FIGS. 1-3. Instead, the high-temperature fiber-free thermocouple 100 could be assembled with a thermocouple connector 130 on both ends of the thermocouple wire 110. The thermocouple connector 130 on one or both ends may be either a male or female thermocouple connector. The use of two thermocouple connectors 130 on both ends of the thermocouple wire 110 may be referred to as a thermocouple extension.

Additionally, in another embodiment without departing from the invention, the high-temperature fiber-free thermocouple 100, such as the thermocouple wire 110 and/or the thermocouple connector 130 may be covered in a protective braid or sheath to provide additional abrasion resistance.

The end users of the high-temperature fiber-free thermocouple may be thermoplastic aerospace parts manufacturers. Other end users of the high-temperature fiber-free thermocouple 100 utilizing thermoplastic composites may be identified as similar to thermoplastic aerospace parts manufacturers. The thermoplastic aerospace parts manufacturers are a growing niche segment of aerospace market that is developing next generation of composites for use on flight critical surfaces. Currently, only European and American companies are performing this type of work, but expecting China will join once technology becomes more commercialized.

While the invention has been described in detail in terms of specific examples including presently preferred modes of carrying out the invention, those skilled in the art will appreciate that there are numerous variations and permutations of the above described systems and methods.

It is to be understood that the invention is not limited in its application to the details of construction and the arrangement of the components set forth herein. The invention is capable of other embodiments and of being practiced or being carried out in various ways. Variations and modifications of the foregoing are within the scope of the present invention. It should be understood that the invention disclosed and defined herein extends to all alternative combinations of two or more of the individual features mentioned or evident from the text and/or drawings. All of these different combinations constitute various alternative aspects of the present invention. The embodiments described herein explain the best modes known for practicing the invention and will enable others skilled in the art to utilize the invention.

While the preferred embodiments of the invention have been shown and described, it will be apparent to those skilled in the art that changes and modifications may be made therein without departing from the spirit of the invention, the scope of which is defined by this description.

We claim:

1. A high-temperature thermocouple, the thermocouple comprising:
a thermocouple wire including a first conductor and a second conductor twisted together, the first conductor and the second conductor covered with a polyimide-based leak-proof insulation coating, wherein the first conductor and the second conductor are dissimilar wires;
a welded hot junction located at a first end of the thermocouple wire attaching the first conductor and the second conductor of the thermocouple wire; and
a high-temperature thermocouple connector located at a second end opposite the first end of the thermocouple wire,
wherein the thermocouple wire and the high-temperature thermocouple connector are rated at 800 degrees F. and up to 150 PSI.

2. The high-temperature thermocouple of claim 1, wherein the twisted first conductor and the second conductor have a lay length of between 0.3 and 2.5 inches.

3. The high-temperature thermocouple of claim 1, wherein the polyimide-based insulation coating is rated at 800 degrees F. and provides a leak-proof insulation up to 150 PSI.

4. The high-temperature thermocouple of claim 1, wherein the high-temperature thermocouple connector is coated with a high-temperature polyimide resin.

5. The high-temperature thermocouple of claim 1, wherein the first conductor and the second conductor are between size 20-36 AWG.

6. The high-temperature thermocouple of claim 1, wherein a thickness of the insulation coating is approximately 0.005 inches.

7. The high-temperature thermocouple of claim 1, wherein the first conductor and the second conductor are dipped in a polyimide precursor-polyamic acid and heat cured.

8. The high-temperature thermocouple of claim 1, wherein the welded hot junction is insulated.

9. The high-temperature thermocouple of claim 8, wherein the welded hot junction insulation is a fluoropolymer.

10. The high-temperature thermocouple of claim 8, wherein the welded hot junction insulation is a polyimide-based material.

11. The high-temperature thermocouple of claim 1, wherein the thermocouple wire and the high-temperature thermocouple connector are rated at 200 PSI.

12. A high-temperature thermocouple, the thermocouple comprising:
a thermocouple wire that includes a pair of dissimilar wires twisted around each other, wherein the thermocouple wire is covered with a polyimide-based leak-proof insulation coating wherein the polyimide-based insulation coating is rated at 800 degrees F. and provides a leak-proof insulation up to 150 PSI;
a welded hot junction located at a first end of the thermocouple wire attaching the pair of dissimilar wires, wherein the welded hot junction is insulated with one of a fluoropolymer or a polyimide-based material; and
a high-temperature thermocouple connector located at a second end opposite the first end of the thermocouple wire,
wherein the thermocouple wire is rated at 800 degrees F. and up to 150 PSI.

13. The high-temperature thermocouple of claim 12, wherein the twisted pair of dissimilar wires have a lay length of between 0.3 and 2.5 inches.

14. The high-temperature thermocouple of claim 12, wherein the high-temperature thermocouple connector is coated with a high-temperature polyimide resin.

15. The high-temperature thermocouple of claim 12, wherein the pair of dissimilar wires have between size 20-36 AWG.

16. The high-temperature thermocouple of claim 12, wherein a thickness of the insulation coating is approximately 0.005 inches.

17. A method for making a high-temperature thermocouple, the method comprising:
coating a pair of dissimilar wires with a leak-proof insulation coating, the insulation coating is a polyimide-based insulation coating, wherein the coating includes:
dipping the pair of dissimilar wires in a liquid polyimide-based solution; and
curing the pair of dissimilar wires with heat;
twisting the pair of dissimilar wires around themselves with a lay length between approximately 0.3 and 2.5 inches;
welding together the pair of dissimilar wires to each other at a first end, thereby creating a welded hot junction located at the first end of the pair of dissimilar wires; and
attaching a second end opposite the first end of the pair of dissimilar wires to a high-temperature thermocouple connector,
wherein the leak-proof insulation coating and high-temperature thermocouple connector are rated for 800 degree F. and 150 PSI.

18. The method for making the high-temperature thermocouple of claim 17, wherein the liquid polyimide-based solution and insulation coating is a polyimide precursor-polyamic acid.

19. The method for making the high-temperature thermocouple of claim 17, wherein the welded hot junction is insulated with one of a fluoropolymer or a polyimide-based material.

20. The method for making the high-temperature thermocouple of claim 17, wherein a thickness of the insulation coating is approximately 0.005 inches.
